(19) United States
(12) Patent Application Publication
(10) Pub. No.: US 2024/0429268 A1
(43) Pub. Date: Dec. 26, 2024

(54) SEMICONDUCTOR DEVICE AND MANUFACTURING METHOD THEREOF

(71) Applicant: SAMSUNG ELECTRONICS CO., LTD., Suwon-si (KR)

(72) Inventors: Taekyun KIM, Suwon-si (KR); Jaewon SHIM, Suwon-si (KR); Jaejin CHUNG, Suwon-si (KR)

(73) Assignees: SAMSUNG ELECTRONICS CO., LTD., Suwon-si (KR); Korea University Research And Business Foundation, Seoul (KR)

(21) Appl. No.: 18/651,934

(22) Filed: May 1, 2024

(30) Foreign Application Priority Data
Jun. 21, 2023 (KR) 10-2023-0079934

(51) Int. Cl. H01G 4/06

(52) U.S. Cl. CPC H01L 28/75

(57) ABSTRACT

A semiconductor device includes a capacitor including a first electrode, a second electrode, and a dielectric layer between the first electrode and the second electrode, where at least one of the first electrode and the second electrode includes a nanolaminate electrode, the nanolaminate electrode includes a plurality of first material layers and a plurality of second material layers, the plurality of first material layers and the plurality of second material layers being alternately arranged, the plurality of first material layers includes indium oxide (In₂O₃), the plurality of second material layers includes molybdenum oxide (MoOₓ), each of the plurality of first material layers has a thickness between about 2 angstroms to about 6 angstroms, and each of the plurality of second material layers includes a monolayer of molybdenum oxide.

### CROSS-REFERENCE TO RELATED APPLICATION

This application is based on and claims priority to Korean Patent Application No. 10-2023-0079934, filed on Jun. 21, 2023, in the Korean Intellectual Property Office, the disclosure of which is incorporated by reference herein in its entirety.

### BACKGROUND

Example embodiments of the disclosure relate to a semiconductor device and a manufacturing method thereof, and more particularly, to a semiconductor device including capacitors and a manufacturing method thereof.

Depending on the downscaling of the semiconductor device, the sizes of the capacitors used in a dynamic random access memory (DRAM) device, for example, are also being reduced. As the sizes of the capacitors decrease, the leakage current increases.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Provided is a semiconductor device including a capacitor with a relatively high capacitance in a high frequency region while having a reduced leakage current by employing an electrode material with a high work function.

Additional aspects will be set forth in part in the description which follows and, in part, will be apparent from the description, or may be learned by practice of the presented embodiments.

According to an aspect of an example embodiment, a semiconductor device may include a capacitor including a first electrode, a second electrode, and a dielectric layer between the first electrode and the second electrode, where at least one of the first electrode and the second electrode includes a nanolaminate electrode, the nanolaminate electrode includes a plurality of first material layers and a plurality of second material layers, the plurality of first material layers and the plurality of second material layers being alternately arranged, the plurality of first material layers includes indium oxide (In₂O₃), the plurality of second material layers includes molybdenum oxide (MoOₓ), each of the plurality of first material layers has a thickness between about 2 angstroms to about 6 angstroms, and each of the plurality of second material layers includes a monolayer of molybdenum oxide.

According to an aspect of an example embodiment, a semiconductor device may include a capacitor including a first electrode, a second electrode, and a dielectric layer between the first electrode and the second electrode, where at least one of the first electrode and the second electrode includes a nanolaminate electrode, the nanolaminate electrode includes a plurality of first material layers including indium oxide (In₂O₃) and a plurality of second material layers respectively arranged between two adjacent first material layers of the plurality of first material layers, each of the plurality of second material layers including a monolayer of molybdenum oxide (MoOₓ), and the nanolaminate electrode has a work function between about 4.95 eV to about 5.05 eV.

According to an aspect of an example embodiment, a semiconductor device may include a substrate, a contact structure on the substrate, a lower electrode on the contact structure, having a cylinder shape, and including a first nanolaminate electrode, a dielectric layer on the lower electrode, and an upper electrode on the dielectric layer, where the first nanolaminate electrode includes a plurality of first material layers including indium oxide (In₂O₃) and a plurality of second material layers respectively arranged between two adjacent first material layers of the plurality of first material layers, each of the plurality of second material layers including a monolayer of molybdenum oxide (MoOₓ), and the first nanolaminate electrode has a work function between about 4.95 eV to about 5.05 eV.

According to an aspect of an example embodiment, a method of manufacturing a semiconductor device may include forming a nanolaminate electrode on a substrate by repeating a deposition cycle of a material layer pair k number of times, the material layer pair including a first material layer and a second material layer, where the deposition cycle of the material layer pair includes repeating a first material layer deposition cycle m number of times on the substrate, the first material layer deposition cycle including depositing indium oxide (In₂O₃) and repeating a second material layer deposition cycle n number of times on the substrate, the second material layer deposition cycle including depositing molybdenum oxide (MoOₓ), where m is in a range of 10 to 30 and n is 1.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor device according to one or more example embodiments;

FIG. 2 is a cross-sectional view of a first electrode of FIG. 1 according to one or more example embodiments;

FIG. 3 is a cross-sectional view of a second electrode of FIG. 1 according to one or more example embodiments;

FIG. 4 is a timing diagram illustrating a method of manufacturing a nanolaminate electrode according to one or more example embodiments;

FIG. 5 is a flowchart illustrating a first material layer deposition cycle according to one or more example embodiments;

FIG. 6 is a flowchart illustrating a second material layer deposition cycle according to one or more example embodiments;

FIG. 7 is an X-ray diffraction analysis graph of a nanolaminate electrode according to one or more example embodiments;

FIG. 8 is a graph illustrating binding energy of a nanolaminate electrode, which is measured by ultraviolet photoelectron spectroscopy (UPS), according to one or more example embodiments;

FIG. 9 is a graph illustrating resistivity, carrier concentration, and mobility of a nanolaminate electrode according to one or more example embodiments;

FIG. 10 illustrates images showing a surface morphology of a nanolaminate electrode, which is measured using an atomic force microscopy (AFM), according to one or more example embodiments;

FIG. 11 is a scanning electron microscopy image of a capacitor according to a comparative example;

FIG. 12 is a scanning electron microscopy image of a capacitor according to one or more example embodiments;

FIG. 13 is an energy band diagram of a capacitor according to a comparative example;

FIG. 14 is an energy band diagram of a capacitor according to one or more example embodiments;

FIG. 15 is a graph illustrating capacitance with respect to a frequency of a capacitor according to one or more example embodiments;

FIG. 16 is a graph illustrating capacitance in a high frequency region of a capacitor according to one or more example embodiments;

FIG. 17 is a graph illustrating current density versus voltage characteristics of a capacitor according to one or more example embodiments;

FIG. 18 is a cross-sectional view illustrating a semiconductor device according to one or more example embodiments;

FIG. 19 is an enlarged view of a portion A of FIG. 18 according to one or more example embodiments;

FIG. 20 is a cross-sectional view illustrating a semiconductor device according to one or more example embodiments;

FIG. 21 is a cross-sectional view illustrating a semiconductor device according to one or more example embodiments; and

FIG. 22 is a cross-sectional view illustrating a semiconductor device according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

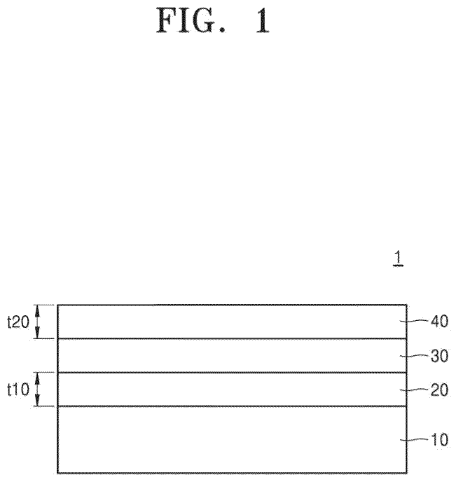

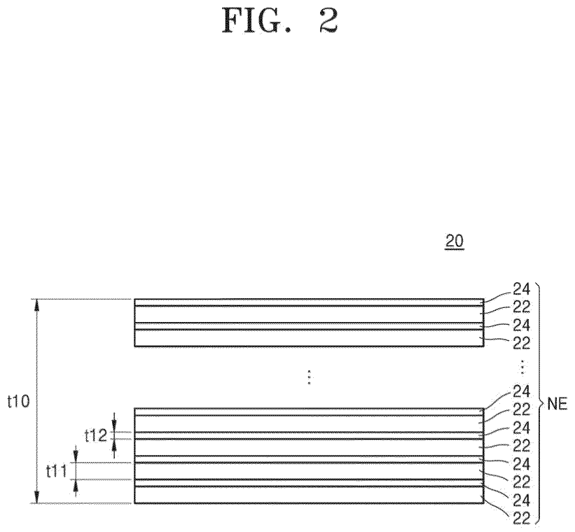

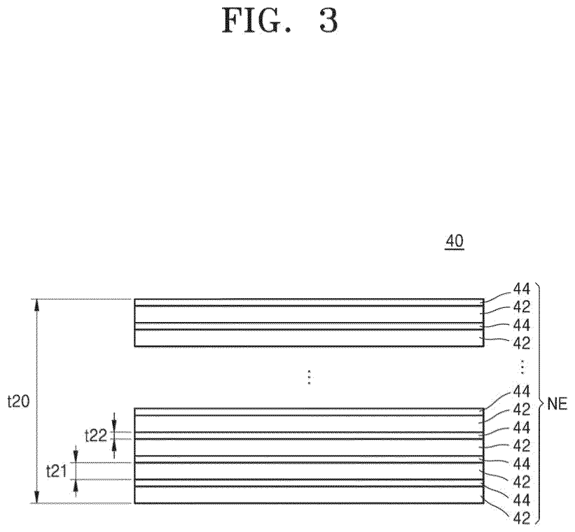

FIG. 1 is a cross-sectional view illustrating a semiconductor device 1 according to one or more example embodiments. FIG. 2 is a cross-sectional view of a first electrode 20 of FIG. 1 according to one or more example embodiments. FIG. 3 is a cross-sectional view of a second electrode 40 of FIG. 1 according to one or more example embodiments.

Referring to FIG. 1, the semiconductor device 1 may include a substrate 10, a first electrode 20, a dielectric layer 30, and a second electrode 40. For example, the first electrode 20, the dielectric layer 30, and the second electrode 40 may constitute a capacitor (for example, a capacitor with a metal-insulator-metal (MIM) structure).

The first electrode 20 may include a nanolaminate electrode NE as described with reference to FIG. 2. The nanolaminate electrodes NE may include a plurality of first material layers 22 and a plurality of second material layers 24, which are alternately arranged.

In some embodiments, the plurality of first material layers 22 may include indium oxide (In₂O₃). For example, the plurality of first material layers 22 may be formed by an atomic layer deposition (ALD) process, and each of the plurality of first material layers 22 may have a first thickness t11 of about 2 angstroms to about 6 angstroms.

In some embodiments, the plurality of second material layers 24 may include molybdenum oxide (MoOₓ). For example, the plurality of second material layers 24 may be formed by the ALD process and may have a second thickness t12 of about 1 angstrom or less.

For example, each of the plurality of second material layers 24 may include a monolayer of molybdenum oxide. In some embodiments, each of the plurality of second material layers 24 may form a single layer continuously extending as shown in FIG. 2. In some embodiments, each of the plurality of second material layers 24 may be formed as island-shaped particles or aggregates arranged on the top surface of the first material layer 22.

For example, the monolayer of molybdenum oxide may refer to all of the single-layer continuously extending as the molybdenum oxide, or island-shaped particles or aggregates. For example, the monolayer of molybdenum oxide may be formed by repeating the second material layer deposition cycle of the ALD process n times, where n may be 1. However, in some embodiments, the monolayer of molybdenum oxide may be formed by repeating the second material layer deposition cycle of the ALD process n times, where n may be any number from among 1 to 5.

The first electrode 20 may be formed by repeatedly performing, at a predetermined ratio, a first material layer deposition cycle to form each of the plurality of first material layers 22 and a second material layer deposition cycle to form each of the plurality of second material layers 24. For example, the first material layer deposition cycle and the second material layer deposition cycle may be repeatedly performed, such that the first material layer deposition cycle is performed until the first material layer 22 is formed to have a first thickness t11 of about 2 angstroms to about 6 angstroms, after which the second material layer deposition cycle is performed to form a monolayer of molybdenum oxide, after which the first material layer deposition cycle is performed until the first material layer 22 is formed to have the first thickness t11 of about 2 angstroms to about 6 angstroms, after which the second material layer deposition cycle is then performed to form the monolayer of molybdenum oxide. The processes may be repeated until the desired structure is constructed. The first electrode 20 may have a thickness t10 of, for example, about 10 nanometers to about 50 nanometers.

In some embodiments, the dielectric layer 30 may include a metal oxide that is a high-k dielectric material. In some embodiments, the dielectric layer 30 may include titanium oxide. In some embodiments, the dielectric layer 30 may include at least one of zirconium oxide, hafnium oxide, niobium oxide, tantalum oxide, yttrium oxide, strontium titanium oxide, barium strontium titanium oxide, scandium oxide, and lanthanide oxide.

The second electrode 40 may include a nanolaminate electrode NE as described with reference to FIG. 3. The nanolaminate electrodes NE may include a plurality of first material layers 42 and a plurality of second material layers 44, which are alternately arranged.

In some embodiments, the plurality of first material layers 42 may include indium oxide (In₂O₃). For example, the plurality of first material layers 42 may be formed by an ALD process, and each of the plurality of first material layers 42 may have a first thickness t21 of about 2 angstroms to about 6 angstroms.

In some embodiments, the plurality of second material layers 44 may include molybdenum oxide (MoOₓ). For example, the plurality of second material layers 44 may be formed by the ALD process and may have a second thickness t22 of about 1 angstrom or less. The second electrode 40 may have a thickness t20 of, for example, about 10 nanometers to about 50 nanometers.

For example, each of the plurality of second material layers 44 may include a monolayer of molybdenum oxide. In some embodiments, each of the plurality of second material layers 44 may form a single layer continuously extending as shown in FIG. 3. In some embodiments, each of the plurality of second material layers 44 may be formed as island-shaped particles or aggregates arranged on the top surface of the first material layer 42.

In some embodiments, the nanolaminate electrode NE illustrated in FIGS. 2 and 3 may have a work function of about 4.95 eV to about 5.05 eV. Since the nanolaminate electrode NE is formed in a stacked structure of indium oxide and molybdenum oxide having a relatively high work function, the nanolaminate electrode NE may have a higher work function than the work function (e.g., 4.5 eV) of an electrode according to a comparative example such as titanium nitride (TiN).

In some embodiments, the nanolaminate electrode NE shown in FIGS. 2 and 3 may exhibit a first peak derived from an indium oxide (222) plane having a cubic structure at 30.48±0.02° and a second peak derived from an indium oxide (400) plane at 35.43±0.02° in an X-ray diffraction analysis result. In some embodiments, the nanolaminate electrode NE shown in FIGS. 2 and 3 may have a surface roughness of 1 nm or less, for example, in a range of about 0.6 nm to about 1.0 nm.

In some embodiments, the nanolaminate electrode NE illustrated in FIGS. 2 and 3 may have a carrier concentration higher than or equal to the carrier concentration of indium oxide. In addition, the nanolaminate electrode NE shown in FIGS. 2 and 3 may have a resistivity lower than or equal to that of indium oxide. For example, when the first material layer 22 of the nanolaminate electrode NE is formed with a thickness t11 of about 2 angstroms to about 6 angstroms, the resistivity of the nanolaminate electrode NE may be in the range of about 0.1 times to about 1 times the resistivity of the indium oxide.

In some embodiments, the first electrode 20, the dielectric layer 30, and the second electrode 40 may constitute an MIM type capacitor, which may have a relatively high capacitance value throughout the entire frequency range from a low-frequency region to a high-frequency region. For example, the capacitor may have a first capacitance at 1 kHz and a second capacitance at 1 MHz, and the second capacitance may be greater than 50% of the first capacitance (for example, greater than 80% of the first capacitance). In addition, the capacitor may have a significantly lower leakage current as compared to a capacitor that, for example, includes titanium nitride as an electrode.

In some embodiments, when the first material layer 22 of the nanolaminate electrode NE is formed to have a thickness t11 of about 2 angstroms to about 6 angstroms and second material layers 24 each composed of a monolayer of molybdenum oxide are respectively formed between the plurality of first material layers 22, the nanolaminate electrode NE may exhibit a high work function, high carrier mobility, low resistivity, and low surface roughness. Further, a capacitor including the same may have a relatively high capacitance value from a low frequency region to a high frequency region, and may have a remarkably low leakage current.

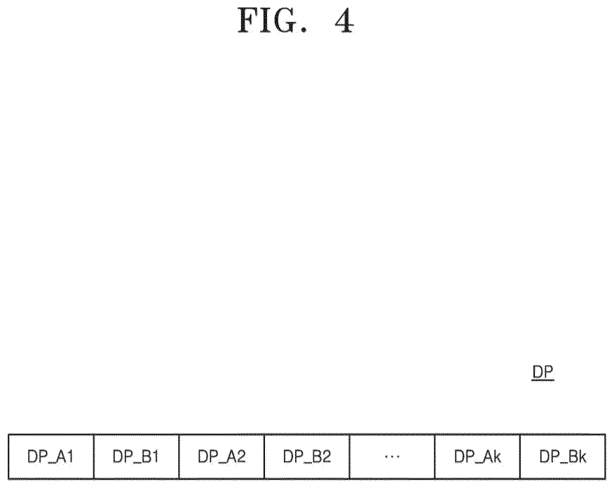

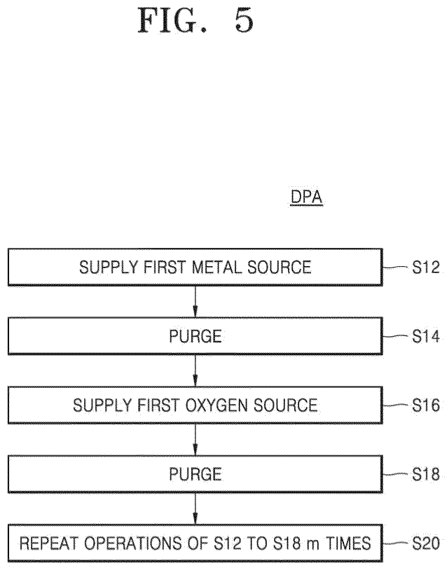

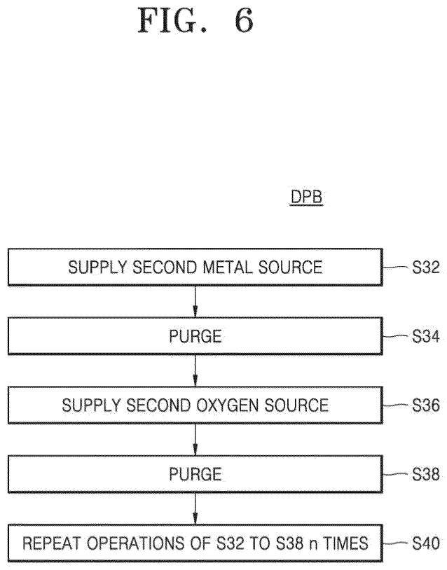

FIG. 4 is a timing diagram illustrating a method DP of manufacturing a nanolaminate electrode according to one or more example embodiments. FIG. 5 is a flowchart illustrating a first material layer deposition cycle DPA according to one or more example embodiments. FIG. 6 is a flowchart illustrating a second material layer deposition cycle DPB according to one or more example embodiments.

Referring to FIGS. 4 to 6, the method DP of manufacturing a nanolaminate electrode may be an ALD process-based method. For example, the nanolaminate electrode may be formed by sequentially and repeatedly performing a first material layer deposition cycle DPA and a second material layer deposition cycle DPB on a substrate in a reaction chamber. The first material layer deposition cycle DPA and the second material layer deposition cycle DPB may be collectively referred to as a deposition cycle of a material layer pair.

For example, as shown in FIG. 4, a nanolaminate electrode may be formed by first performing a first cycle DP_A1 of a first material layer, followed by a first cycle DP_B1 of a second material layer, sequentially followed by a second cycle DP_A2 of the first material layer and a second cycle DP_B2 of the second material layer, and followed by a kth cycle DP_Ak of the first material layer and a kth cycle DP_Bk of the second material layer, with various repeated operations therebetween as needed to form the overall desired structure. That is, the deposition cycle of the material layer pair may be repeated k times. The range of k may be determined in consideration of the total thickness of the nanolaminate electrode, the growth rate of the material layer in each cycle, and the like.

As shown in FIG. 5, the first material layer deposition cycle DPA may include a unit cycle that sequentially includes supplying a first metal source (for example, a metal source including indium) (operation S12), purging (operation S14), supplying a first oxygen source (operation S16), and purging (operation S18). As shown in operation S20, the first material layer deposition cycle DPA may include sequentially repeating operations S12 to S18 m number of times, where m may range from 10 to 30, approximately.

In one or more example embodiments, in the supplying of a first metal source of operation S12, the first metal source may be supplied into the reaction chamber, and the first metal source may include an organic metal precursor including indium. The first metal source may include at least one of trimethyl indium (In(CH₃)₃) (TMIn), [1,1,1-trimethyl-N-(trimethylsilyl)silanaminato]indium (InCA-1), [3-(dimethylamino)propyl]dimethylindium (DADI), and cyclopentadienyl indium (InCp). In some embodiments, the first metal source may be DADI, but is not limited thereto. For example, the supplying of a first metal source of operation S12 may be performed for a period of about 0.5 seconds to about 3 seconds.

Thereafter, in the purging of operation S14, an excessive first metal source that has not been adsorbed on the substrate may be purged and/or removed.

In the supplying of a first oxygen source of operation S16, a first oxygen source may be supplied in the reaction chamber, and the first oxygen source may include at least one of hydrogen peroxide, oxygen, ozone, and oxygen plasma. The first oxygen source may also be referred to as a reactant. In the supplying of a first oxygen source of operation S16, a reaction between the first metal source adsorbed on the substrate and the first oxygen source may occur to form a first material layer including indium oxide. For example, the supplying of a first oxygen source of operation S16 may be performed for a period of about 1 second to about 20 seconds.

Thereafter, in the purging of operation S18, an excessive first oxygen source that has not been adsorbed on the substrate may be purged and/or removed.

For example, indium oxide with a thickness of approximately 0.15 angstroms to 0.20 angstroms may be formed during a unit cycle that sequentially includes supplying a first metal source (operation S12), purging (operation S14), supplying a first oxygen source (operation S16), and purging (operation S18). When m, which is the number of repetitions of the unit cycle in the first material layer deposition cycle DPA, is less than 10, it may be difficult for the first material layer (indium oxide) to be formed to have a thickness sufficiently thick to crystallize, and, when m is greater than 30, the first material layer (indium oxide) is formed to have too a large thickness, and thus the nanolaminate electrode may have a relatively large resistivity or a relatively low work function.

As shown in FIG. 6, the second material layer deposition cycle DPB may include a unit cycle that sequentially includes supplying a second metal source including molybdenum (operation S32), purging (operation S34), supplying a second oxygen source (operation S36), and purging (operation S38). As shown in operation S40, the second material layer deposition cycle DPB may include sequentially repeating operations S32 to S38 n number of times, where n may be at least 1.

In some embodiments, in the supplying of a second metal source of operation S32, the second metal source may be supplied into the reaction chamber, and the second metal source may include an organic metal precursor including molybdenum. The first metal source may include at least one of bis(tert-butylimido) bis(dimethylamido) molybdenum (TBDMMo), bis(ethylbenzene) molybdenum, MoF₆, MoCl₆, and Mo(CO)₆. In some embodiments, the second metal source may be TBDMMo, but is not limited thereto. For example, the supplying of a second metal source of operation S32 may be performed for a period of about 0.5 seconds to about 5 seconds.

Thereafter, in the purging of operation S34, an excessive second metal source that has not been adsorbed on the substrate may be purged and/or removed.

In the supplying of a second oxygen source of operation S36, a second oxygen source may be supplied in the reaction chamber, and the second oxygen source may include at least one of hydrogen peroxide, oxygen, ozone, and oxygen plasma. The second oxygen source may also be referred to as a reactant. In the supplying of a second oxygen source of operation S36, a reaction between the second metal source adsorbed on the first material layer and the second oxygen source may occur to form a second material layer including molybdenum oxide. For example, a monolayer of molybdenum oxide may be formed on the first material layer. For example, the supplying of a second oxygen source of operation S36 may be performed for a period of about 1 second to about 20 seconds.

Thereafter, in the purging of operation S38, an excessive second oxygen source that has not been adsorbed on the substrate may be purged and/or removed.

For example, molybdenum oxide with a thickness of approximately 1 angstroms or less, or approximately 0.15 angstroms to 0.20 angstroms may be formed during a unit cycle that sequentially includes supplying a second metal source (operation S32), purging (operation S34), supplying a second oxygen source (operation S36), and purging (operation S38). In the second material layer deposition cycle DPB, n, which is the number of repetitions of the unit cycle, may be 1.

In some embodiments, the second material layer composed of a monolayer of molybdenum oxide may be formed as a single layer arranged on the first material layer and continuously extending or may be formed as island-shaped particles or aggregates arranged on the top surface of the first material layer. In some embodiments, since the molybdenum atom has a relatively small ionic radius, the molybdenum atom may be arranged to occupy an interstitial site in which an indium atom is not occupied inside the first material layer.

A ratio of m, which corresponds to a number of times of repeating a unit cycle in the first material layer deposition cycle DPA, and n, which corresponds to a number of times of repeating a unit cycle in the second material layer deposition cycle DPB, may be determined to be approximately 10:1 to 30:1. For example, when the first material layer deposition cycle DPA and the second material layer deposition cycle DPB are performed in the range of approximately 10:1 to 30:1, the nanolaminate electrode may be formed to have a high work function, high carrier mobility, low resistivity, and low surface roughness.

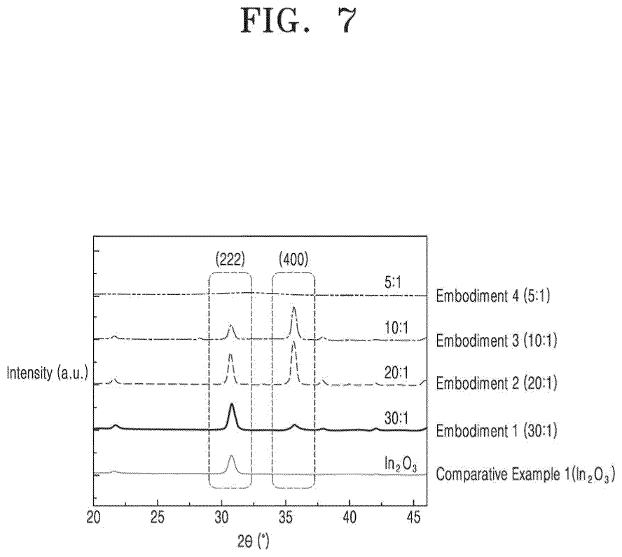

Hereinafter, physical and electrical properties of the nanolaminate electrode according to a ratio of the number of times of the first material layer deposition cycle DPA and the second material layer deposition cycle DPB will be described with reference to FIGS. 7 to 17.

### Experimental Example 1

As shown in Table 1, the first material layer deposition cycle DPA and the second material layer deposition cycle DPB were performed at a ratio of each of approximately 30:1, 20:1, 10:1, and 5:1 on the substrate in the ALD apparatus to form a nanolaminate electrode with a total thickness of about 20 nm. As a comparative example, only the first material layer deposition cycle DPA was performed to form a single layer electrode of indium oxide (In₂O₃).

TABLE 1

| | In₂O₃:MoOₓ | Growth rate | In₂O₃ unit |
|---|---|---|---|
| | Composition | per cycle | thickness |
| No. | Ratio | (angstroms) | (angstrom) |
| Comparative | In₂O₃ only | 0.16 | |
| Example | | | |
| Embodiment 1 | 30:1 | 0.19 | 5.8 |
| Embodiment 2 | 20:1 | 0.20 | 4.0 |
| Embodiment 3 | 10:1 | 0.18 | 1.8 |
| Embodiment 4 | 5:1 | 0.15 | 0.75 |

FIG. 7 is an X-ray diffraction analysis graph of a nanolaminate electrode according to one or more example embodiments.

Referring to FIG. 7, the X-ray diffraction analysis graphs of embodiments 1 to 4 (Table 1) are shown together with the X-ray diffraction analysis graph of a comparative example (Table 1). Embodiments 1 to 3 showed a first peak derived from a plane (222) of indium oxide with a cubic crystal structure and a second peak derived from a plane (400) thereof. The first peak appears at 30.48±0.02° and the second peak appears at 35.43±0.02°. It may be seen that the comparative example and embodiment 4 do not have a peak corresponding the second peak derived from the plane (400). This is because, in the case of embodiments 1 to 3 in which a monolayer of molybdenum oxide is formed in a ratio of each of approximately 30:1, 20:1, and 10:1, the molybdenum oxide monolayer or the molybdenum atom acts as an intermediate layer (insertion layer) or an additive element that improves the degree of crystallinity of indium oxide.

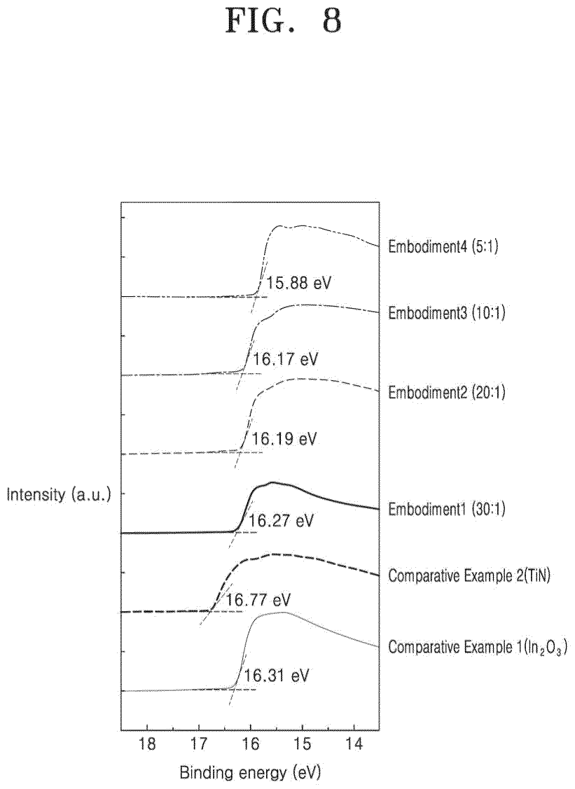

FIG. 8 is a graph illustrating binding energy of a nanolaminate electrode, which is measured by ultraviolet photoelectron spectroscopy (UPS), according to one or more example embodiments.

Referring to FIG. 8, the binding energy of embodiments 1 to 4 is illustrated together with the binding energy of comparative example 1 (indium oxide) and comparative example 2 (titanium nitride). The work functions of embodiments 1 to 4, and comparative examples 1 and 2 calculated from the binding energy measured by ultraviolet photoelectron spectroscopy (UPS) are shown in Table 2.

TABLE 2

| | In₂O₃:MoOₓ | | |
|---|---|---|---|
| | Composition | Binding energy | Work function |
| No. | Ratio | (eV) | (eV) |
| Comparative | In₂O₃ only | 16.31 | 4.91 |
| Example 1 | | | |
| Comparative | TiN only | 16.77 | 4.45 |
| Example 2 | | | |
| Embodiment 1 | 30:1 | 16.27 | 4.95 |
| Embodiment 2 | 20:1 | 16.19 | 5.03 |
| Embodiment 3 | 10:1 | 16.17 | 5.05 |
| Embodiment 4 | 5:1 | 15.88 | 5.34 |

As illustrated in Table 2, as the content of molybdenum increases, the work function increases, and for example, in the case of embodiments 1 to 3 in which the monolayer of molybdenum oxide is formed at a ratio of each of approximately 30:1, 20:1, and 10:1, it may be seen that the work function is relatively high as each of approximately 4.95 eV, 5.03 eV, and 5.05 eV. It may be confirmed that this is a greater value than the work function of each of comparative example 1 (indium oxide) and comparative example 2 (titanium nitride).

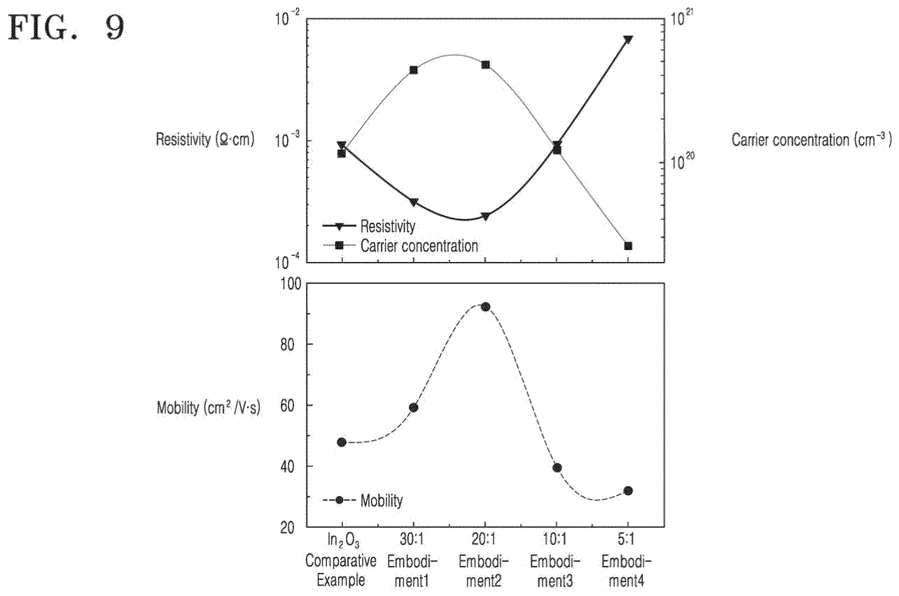

FIG. 9 is a graph illustrating resistivity, carrier concentration, and mobility of a nanolaminate electrode according to one or more example embodiments.

Referring to FIG. 9, it may be confirmed that the resistivity, carrier concentration, and mobility of each of embodiments 1 to 3 were better or equivalent to the resistivity, carrier concentration, and mobility of each of comparative examples. In particular, embodiment 2, in which the monolayer of molybdenum oxide was formed at a ratio of approximately 20:1, showed the highest carrier concentration, the highest charge mobility (for example, the charge mobility of 92.6 cm²/V·s), and the lowest resistivity (for example, the resistivity of 240 μΩ·cm), showing the best electrical characteristics. That is, as embodiments 1 to 3, it may be seen that the nanolaminate electrode in which the indium oxide layer with a thickness of about 2 angstroms to about 6 angstroms and the monolayers of molybdenum oxide are repeatedly formed has the highest carrier concentration and the lowest resistivity.

Embodiment 4, in which the monolayer of molybdenum oxide was formed at a ratio of approximately 5:1, showed lower carrier concentration and mobility than the comparative examples, and highest resistivity, and it may be presumed that this happened because the content of molybdenum increased to induce amorphization of indium oxide or because the free carrier mobility was reduced due to the scattering effect of molybdenum.

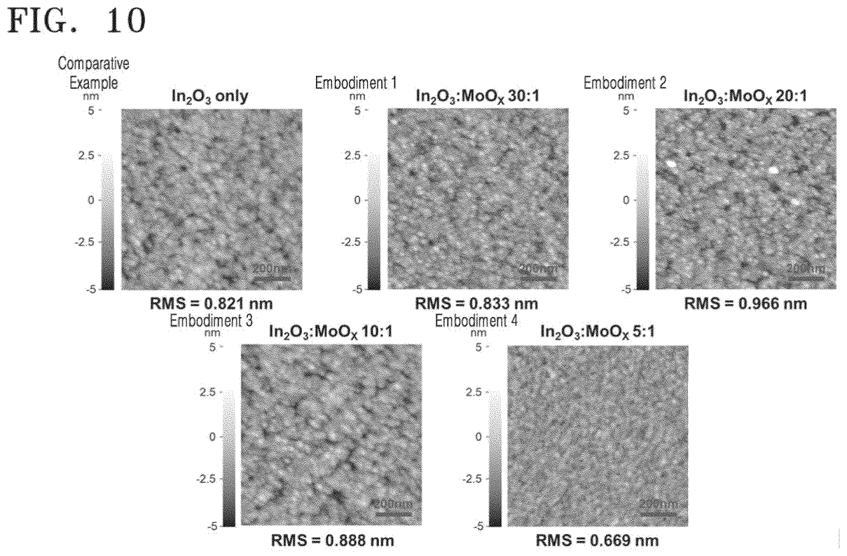

FIG. 10 illustrates images showing a surface morphology of a nanolaminate electrode, which is measured using an atomic force microscopy (AFM), according to one or more example embodiments.

Referring to FIG. 10, embodiments 1 and 2 have a surface roughness value greater than that of the comparative example. That is, in embodiments 1 and 2, as the content of molybdenum increases, the crystallinity of the indium oxide layer is improved, increasing the surface roughness value, and in contrast, embodiment 4 has the smallest surface roughness value. In the case of embodiment 4 in which a monolayer of molybdenum oxide is formed in a ratio of approximately 5:1 with a relatively large amount of molybdenum content, it may be presumed that the surface roughness is the most reduced as the amorphization is induced.

All embodiments 1 to 4 have a surface roughness of 1 nm or less, which may be low enough to reduce leakage current by reducing trap sites at the interface between the dielectric layer and the nanolaminate electrode.

### Experimental Example 2

Capacitors according to embodiments and comparative examples were formed on the substrate in the ALD apparatus, as shown in Table 3.

TABLE 3

| | Comparative | |
|---|---|---|
| | example | Embodiment |
| Lower electrode | TiN 20 nm | In₂O₃:MoOₓ = 20:1, 20 nm |
| Dielectric layer | TiO₂ 21 nm | TiO₂ 21 nm |
| Upper electrode | Ag 44 nm | Ag 44 nm |

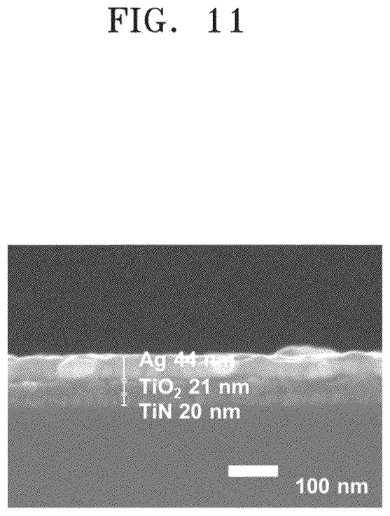

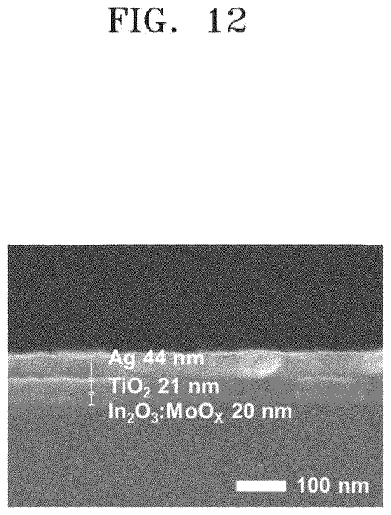

FIG. 11 is a scanning electron microscopy image of a capacitor according to a comparative example. FIG. 12 is a scanning electron microscopy image of a capacitor according to one or more example embodiments.

Referring to FIGS. 11 and 12, it may be seen that a lower electrode of each of the comparative example (FIG. 11) and the embodiment (FIG. 12) is formed as a continuous material layer covering the entire substrate with a uniform thickness. In addition, it may be seen that the interface between the lower electrode and the dielectric layer also has excellent interfacial properties without an interface defect element such as a void or seam.

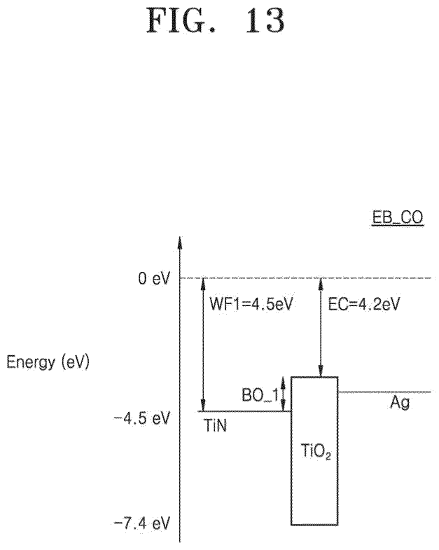

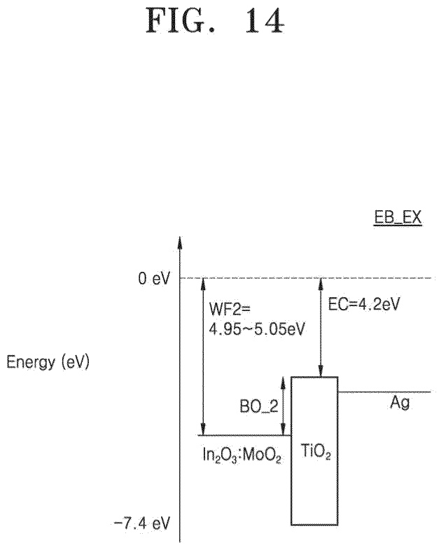

FIG. 13 is an energy band diagram EB_CO of a capacitor according to a comparative example. FIG. 14 is an energy band diagram EB_EX of a capacitor according to an embodiment.

Referring to FIG. 13, the capacitor according to the comparative example has a work function WF1 of the lower electrode TiN of 4.5 eV, and the work function WF1 of the lower electrode TiN has a relatively small difference from 4.2 eV, which is a conduction band EC of the dielectric layer TiO₂. Accordingly, at the interface between the lower electrode and the dielectric layer, the band offset BO_1 has a relatively small value. When the band offset at the interface between the lower electrode and the dielectric layer is small, a leakage current may occur due to thermal electron emission.

Referring to FIG. 14, the capacitor according to the embodiment has a work function WF2 of the lower electrode (In₂O₃:MoOₓ) of 4.95 to 5.05 eV, which is a relatively large difference from the conduction band EC of the dielectric layer (TiO₂) of 4.2 eV. Accordingly, at the interface between the lower electrode and the dielectric layer, the band offset BO_2 has a relatively large value. When the band offset at the interface between the lower electrode and the dielectric layer is large, occurrence of a leakage current may be significantly reduced or lowered.

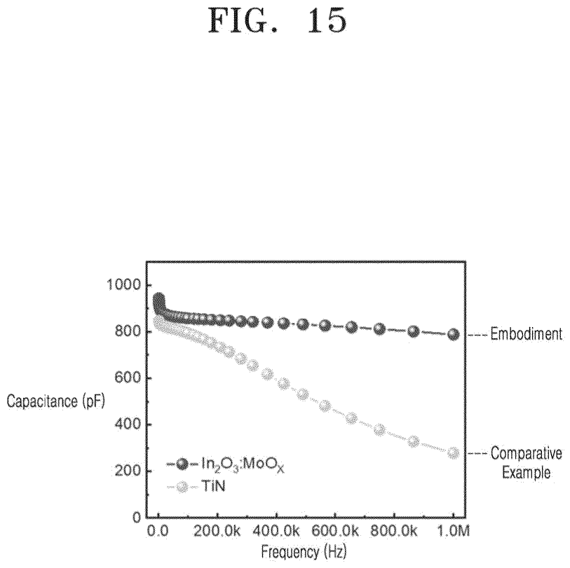

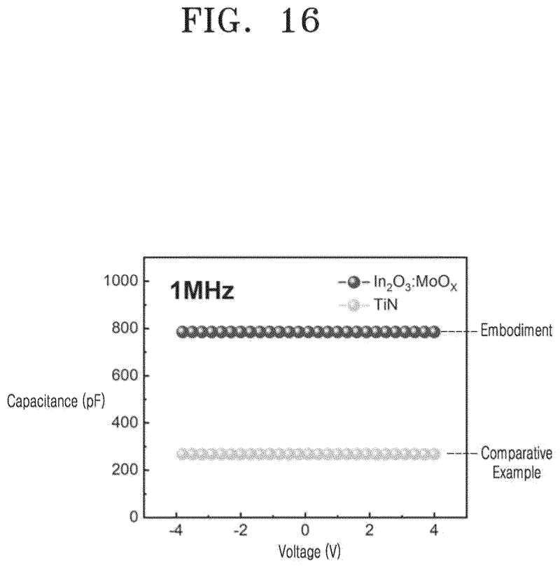

FIG. 15 is a graph illustrating capacitance with respect to a frequency of a capacitor according to one or more example embodiments. FIG. 16 is a graph illustrating capacitance in a high frequency region of a capacitor according to one or more example embodiments.

Referring to FIGS. 15 and 16, the capacitor according to the comparative example has a large capacitance value of 800 pF or more in the low frequency region, but the capacitance value gradually decreases as the frequency increases, and has a capacitance value of 240 pF or less in the high frequency region of 1 MHz. The capacitor according to the embodiment has a large capacitance value of about 950 pF or more in the low frequency region, maintains almost constant capacitance values even if the frequency increases, and has a capacitance value of about 800 pF or less in the high frequency region of 1 MHz.

In other words, although the capacitance value of the embodiment in the low-frequency region is larger than that of the comparative example, exhibiting no significant difference, but the capacitance value of the embodiment in the high-frequency region has a significantly larger value equivalent to three times as that of the comparative example.

In general, it has been known that the equilibrium series resistance component in the low frequency region represents a value corresponding to a dielectric loss due to dielectric relaxation, and as the frequency increases, the influence of the series resistance and the inductance becomes dominant, thereby reducing the capacitance and the equilibrium series resistance being affected by the loss due to the electrode. The lower electrode according to the embodiment has a dielectric loss coefficient of 0.243 at 1 MHz, while the lower electrode according to the comparative example has a dielectric loss coefficient of 1.31 thereat. Therefore, since the lower electrode in the high frequency region according to the embodiment has a significantly lower dielectric loss coefficient than the lower electrode according to the comparative example (i.e., because the carrier mobility of the lower electrode according to the embodiment is high and the resistivity thereof is low), the lower electrode according to the embodiment may be have a high capacitance value.

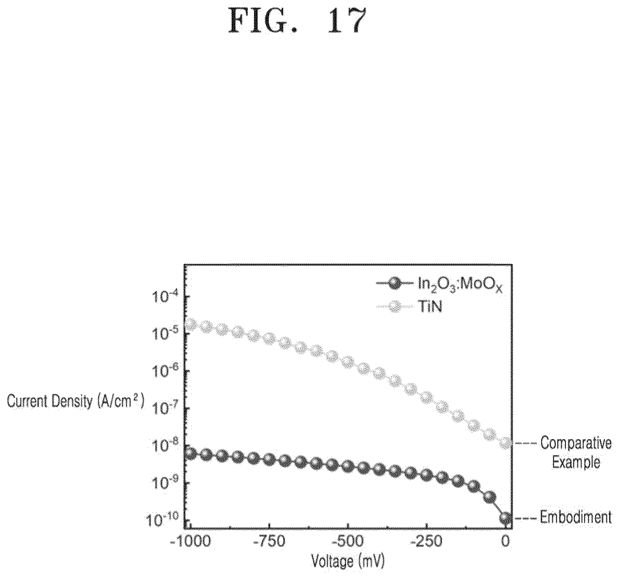

FIG. 17 is a graph illustrating current density versus voltage characteristics of a capacitor according to one or more example embodiments.

Referring to FIG. 17, the capacitor according to the comparative example shows a leakage current density of 1.75×10⁻⁵ at 1000 mV, whereas the capacitor according to the embodiment showed a leakage current of 6.03×10⁻⁹ at 1000 mV, which is about 3000 times lower than that of the comparative example.

A narrow band gap of a titanium oxide used as a dielectric layer may generate a large leakage current due to the Schottky emission at the interface between the dielectric layer and the lower electrode. However, since the lower electrode (referred to as In₂O₃:MoOₓ) according to embodiments has a high work function, the potential barrier between the lower electrode and the dielectric layer may be increased to effectively block the leakage path, thereby reducing the leakage current of the capacitor.

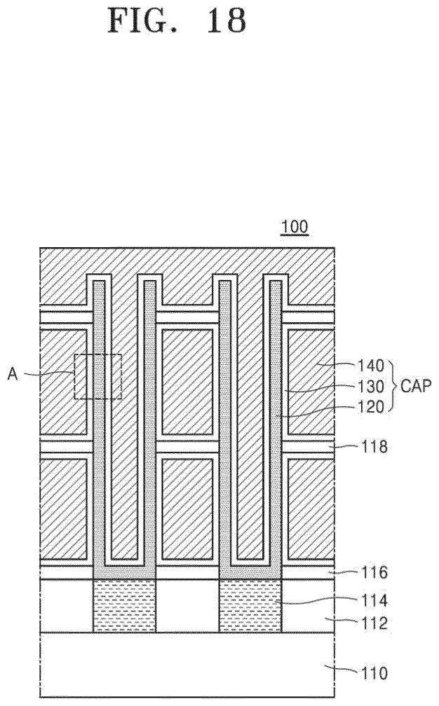

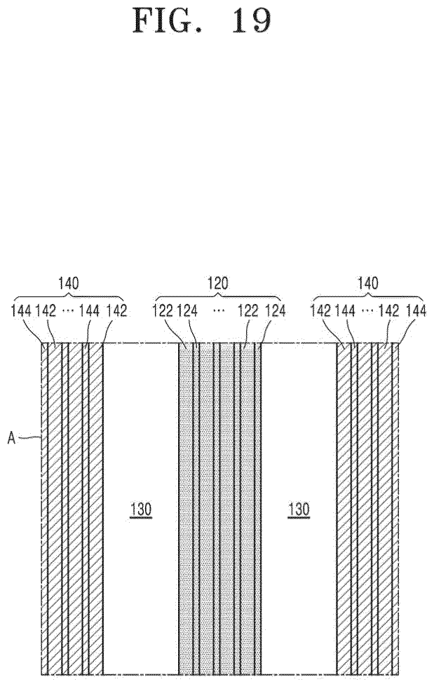

FIG. 18 is a cross-sectional view illustrating a semiconductor device 100 according to one or more example embodiments. FIG. 19 is an enlarged view of a portion A of FIG. 18 according to one or more example embodiments.

Referring to FIGS. 18 and 19, the semiconductor device 100 may include a dynamic random access memory (DRAM) element, and may include a cell transistor formed on the substrate 110 and a capacitor CAP electrically connected to the cell transistor.

A lower insulating layer 112 may be arranged on the substrate 110, and contact structures 114 may be arranged on the substrate 110 to penetrate the lower insulating layer 112. The contact structures 114 may include a conductive material. An etching stop layer 116 having an opening exposing a top surface of each of the contact structures 114 may be arranged on the lower insulating layer 112.

The capacitor CAP may be arranged on the etching stop layer 116. The capacitor CAP may include a lower electrode 120, a dielectric layer 130, and an upper electrode 140. The lower electrode 120 may have a cylinder shape, the side wall of the bottom of the lower electrode 120 may be surrounded by the etching stop layer 116, and the bottom of the lower electrode 120 may be arranged on the top surface of each of the contact structures 114. The lower electrode 120 may be formed at a relatively large height in a vertical direction or may have a large aspect ratio, and a support member 118 may be arranged on a sidewall of the lower electrode 120. The dielectric layer 130 may be arranged conformably on the inner wall and outer wall of the lower electrode 120. The upper electrode 140 may be arranged on the dielectric layer 130 to cover the lower electrode 120.

In some embodiments, the lower electrode 120 may include a plurality of first material layers 122 and a plurality of second material layers 124, which are alternately arranged. The lower electrode 120 may have a structure similar to that of the nanolaminate electrode NE described with reference to FIG. 2. For example, the plurality of first material layers 122 each may include indium oxide having a thickness of about 2 angstroms to about 6 angstroms, and the plurality of second material layers 124 may include a monolayer including molybdenum oxide.

In some embodiments, the dielectric layer 130 may include a metal oxide that is a high dielectric constant material. In some embodiments, the dielectric layer 130 may include titanium oxide. In some embodiments, the dielectric layer 130 may include at least one of zirconium oxide, hafnium oxide, niobium oxide, tantalum oxide, yttrium oxide, strontium titanium oxide, barium strontium titanium oxide, scandium oxide, and lanthanide oxide.

In some embodiments, the upper electrode 140 may include a plurality of first material layers 142 and a plurality of second material layers 144, which are alternately arranged. The upper electrode 140 may have a structure similar to that of the nanolaminate electrode NE described with reference to FIG. 3. For example, the plurality of first material layers 142 each may include indium oxide having a thickness of about 2 angstroms to about 6 angstroms, and the plurality of second material layers 144 may include a monolayer including molybdenum oxide.

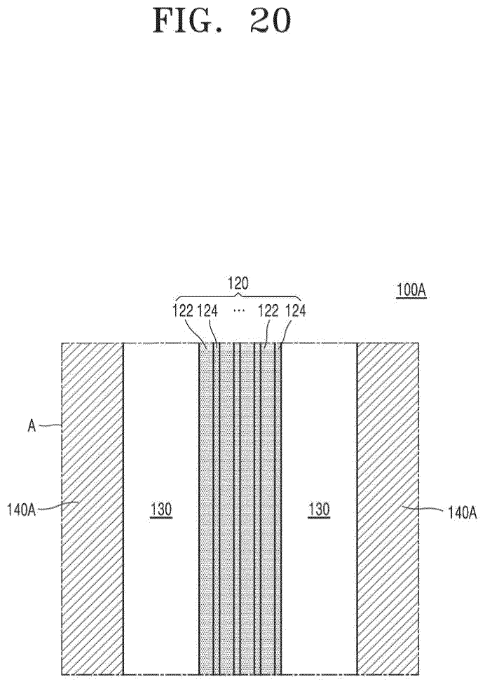

FIG. 20 is a cross-sectional view illustrating a semiconductor device 100A according to one or more example embodiments.

Referring to FIG. 20, the lower electrode 120 may include a nanolaminate electrode including a plurality of first material layers 122 and a plurality of second material layers 124, which are alternately arranged. The upper electrode 140A may include at least one of a metal such as ruthenium (Ru), titanium (Ti), tantalum (Ta), niobium (Nb), iridium (Ir), molybdenum (Mo), tungsten (W), or the like; a conductive metal nitride such as titanium nitride (TiN), tantalum nitride (TaN), niobium nitride (NbN), molybdenum nitride (MoN), tungsten nitride (WN), or the like; and a conductive metal oxide such as iridium oxide (IrO₂), ruthenium oxide (RuO₂), strontium ruthenium oxide (SrRuO₃), or the like.

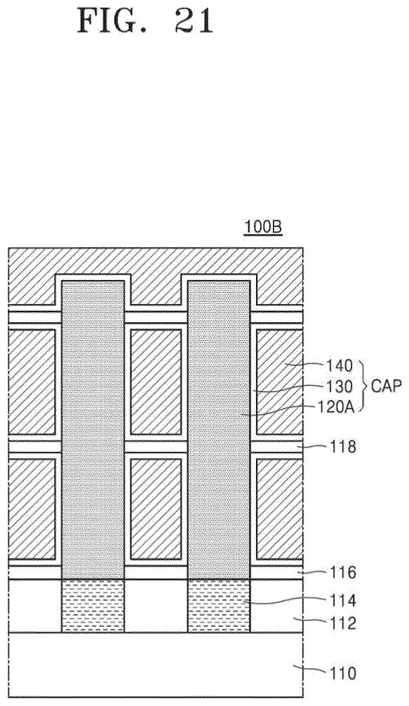

FIG. 21 is a cross-sectional view illustrating a semiconductor device 100B according to one or more example embodiments.

Referring to FIG. 21, a lower electrode 120A may have a pillar shape arranged on a top surface of a contact structure 114 and extending in a vertical direction. A dielectric layer 130 may be arranged conformably on the top surface and sidewalls of the lower electrode 120A.

In some embodiments, the lower electrode 120A may include an integrated material layer extending in a vertical direction, and the lower electrode 120A may include the nanolaminate electrode NE described with reference to FIGS. 1 to 3. According to the manufacturing method in some embodiments, the lower electrode 120A may be formed by forming a mold insulating layer having a pillar-shaped opening on a substrate and forming the nanolaminate electrode NE described with reference to FIGS. 1 to 3 in the opening by using the manufacturing method described with reference to FIGS. 4 to 6.

In some embodiments, the lower electrode 120A may include a base pillar extending in a vertical direction, and an electrode layer conformally arranged on the sidewall and the top surface of the base pillar. The base pillar may include at least one of a metal such as ruthenium (Ru), titanium (Ti), tantalum (Ta), niobium (Nb), iridium (Ir), molybdenum (Mo), tungsten (W), or the like; a conductive metal nitride such as titanium nitride (TiN), tantalum nitride (TaN), niobium nitride (NbN), molybdenum nitride (MoN), tungsten nitride (WN), or the like; and a conductive metal oxide such as iridium oxide (IrO₂), ruthenium oxide (RuO₂), strontium ruthenium oxide (SrRuO₃), or the like, and the electrode layer may include the nanolaminate electrode NE described with reference to FIGS. 1 to 3.

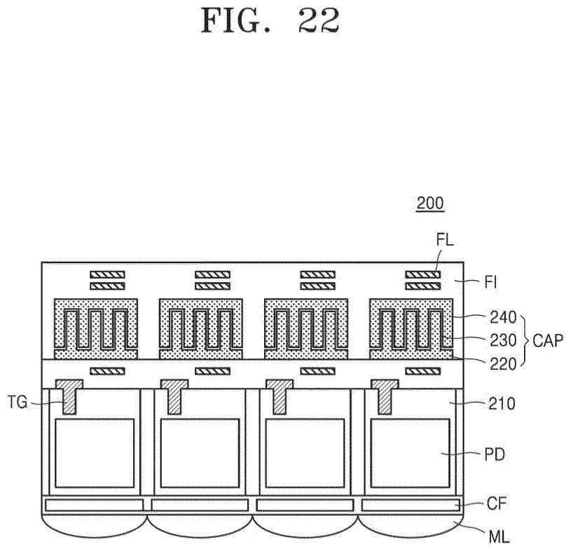

FIG. 22 is a cross-sectional view illustrating a semiconductor device 200 according to one or more example embodiments.

Referring to FIG. 22, the semiconductor device 200 may be a global shutter-type image sensor including a plurality of photoelectric conversion regions PD formed on a semiconductor substrate 210 and a capacitor CAP arranged on a front face of the semiconductor substrate 210. A transmission gate TG may be arranged to extend into the semiconductor substrate 210 and may be configured to control photoelectrons stored in the photoelectric conversion region PD. A pixel transistor may be further formed on the front surface of the semiconductor substrate 210, and the pixel transistor may be electrically connected to the capacitor CAP, and the charges transmitted from the photoelectric change region PD of each pixel may be stored in the capacitor CAP. The capacitor CAP may include a lower electrode 220, a dielectric layer 230, and an upper electrode 240, and at least one of the lower electrode 220 and the upper electrode 240 may include a nanolaminate electrode NE described with reference to FIGS. 1 to 3. A front wiring layer FL may be arranged on the front surface of the semiconductor substrate 210, a front insulating layer FI covering or at least partially covering a front wiring layer FL and the capacitor CAP may be arranged thereon, and a color filter CF and a microlens ML may be arranged on the rear surface of the semiconductor substrate 210.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a capacitor comprising:
a first electrode;
a second electrode; and
a dielectric layer between the first electrode and the second electrode,
wherein at least one of the first electrode and the second electrode comprises a nanolaminate electrode,
wherein the nanolaminate electrode comprises a plurality of first material layers and a plurality of second material layers, the plurality of first material layers and the plurality of second material layers being alternately arranged,
wherein the plurality of first material layers comprises indium oxide (In₂O₃),
wherein the plurality of second material layers comprises molybdenum oxide (MoOₓ),
wherein each of the plurality of first material layers has a thickness between about 2 angstroms to about 6 angstroms, and
wherein each of the plurality of second material layers comprises a monolayer of molybdenum oxide (MoOₓ).

2. The semiconductor device of claim 1, wherein the nanolaminate electrode has a thickness between about 10 nanometers to about 50 nanometers.

3. The semiconductor device of claim 1, wherein the nanolaminate electrode has a work function between about 4.95 eV to about 5.05 eV.

4. The semiconductor device of claim 1, wherein, in an X-ray diffraction analysis result, the nanolaminate electrode exhibits a first peak derived from an indium oxide (222) plane having a cubic structure at 30.48±0.020 and a second peak derived from an indium oxide (400) plane at 35.43±0.02°.

5. The semiconductor device of claim 1, wherein the dielectric layer comprises a high-k dielectric metal oxide.

6. The semiconductor device of claim 1, wherein the dielectric layer comprises titanium oxide (TiO₂).

7. The semiconductor device of claim 1, wherein the nanolaminate electrode comprises a surface roughness of about 1 nm or less.

8. The semiconductor device of claim 1, wherein the capacitor has a first capacitance at a first frequency of about 1 kHz, and a second capacitance at a second frequency of about 1 MHz, the second capacitance being greater than 50% of the first capacitance.

9. The semiconductor device of claim 8, wherein the second capacitance is greater than 80% of the first capacitance.

10. A semiconductor device comprising a capacitor which comprises:
a first electrode;
a second electrode; and
a dielectric layer between the first electrode and the second electrode,
wherein at least one of the first electrode and the second electrode comprises a nanolaminate electrode,
wherein the nanolaminate electrode comprises:
a plurality of first material layers comprising indium oxide (In₂O₃); and
a plurality of second material layers respectively arranged between two adjacent first material layers of the plurality of first material layers, each of the plurality of second material layers comprising a monolayer of molybdenum oxide (MoOₓ), and
wherein the nanolaminate electrode has a work function between about 4.95 eV to about 5.05 eV.

11. The semiconductor device of claim 10, wherein each of the plurality of first material layers has a thickness of about 2 angstroms to about 6 angstroms, and
wherein the nanolaminate electrode has a thickness between about 10 nanometers to about 50 nanometers.

12. The semiconductor device of claim 10, wherein, in an X-ray diffraction analysis result, the nanolaminate electrode exhibits a first peak derived from an indium oxide (222) plane having a cubic structure at 30.48±0.020 and a second peak derived from an indium oxide (400) plane at 35.43±0.02°.

13. The semiconductor device of claim 10, wherein the dielectric layer comprises a high-k dielectric metal oxide.

14. The semiconductor device of claim 10, wherein the dielectric layer comprises titanium oxide (TiO₂).

15. The semiconductor device of claim 10, wherein the nanolaminate electrode comprises a surface roughness of 1 nm or less.

16. The semiconductor device of claim 10, wherein the capacitor has a first capacitance at a first frequency of about 1 kHz, and a second capacitance at a second frequency of about 1 MHz, the second capacitance being greater than 50% of the first capacitance.

17. A semiconductor device comprising;
a substrate;
a contact structure on the substrate;
a lower electrode on the contact structure, having a cylinder shape, and comprising a first nanolaminate electrode;
a dielectric layer on the lower electrode; and
an upper electrode on the dielectric layer,
wherein the first nanolaminate electrode comprises:
a plurality of first material layers comprising indium oxide (In₂O₃); and
a plurality of second material layers respectively arranged between two adjacent first material layers of the plurality of first material layers, each of the plurality of second material layers comprising a monolayer of molybdenum oxide (MoOₓ), and
wherein the first nanolaminate electrode has a work function between about 4.95 eV to about 5.05 eV.

18. The semiconductor device of claim 17, wherein the dielectric layer comprises titanium oxide (TiO₂).

19. The semiconductor device of claim 17, wherein each of the plurality of first material layers has a thickness between about 2 angstroms to about 6 angstroms, and
wherein the first nanolaminate electrode has a thickness between about 10 nanometers to about 50 nanometers.

20. The semiconductor device of claim 17, wherein the upper electrode comprises a second nanolaminate electrode,
wherein the second nanolaminate electrode comprises:
a plurality of third material layers comprising indium oxide (In₂O₃); and
a plurality of fourth material layers respectively arranged between two adjacent third material layers of the plurality of third material layers, each of the plurality of fourth material layers comprising a monolayer of molybdenum oxide (MoOₓ), and
wherein the second nanolaminate electrode has a work function between about 4.95 eV to about 5.05 eV.

21-30. (canceled)
